(19) United States
(12) Patent Application Publication
(10) Pub. No.: US 2009/0051280 A1
(43) Pub. Date: Feb. 26, 2009

(54) LIGHT-EMITTING DEVICE, METHOD FOR MANUFACTURING LIGHT-EMITTING DEVICE, AND SUBSTRATE PROCESSING APPARATUS

(75) Inventors: Kazuki Moyama, Hyogo (JP); Yasushi Yagi, Hyogo (JP); Shingo Watanabe, Hyogo (JP); Chuichi Kawamura, Aichi (JP); Kimihiko Yoshino, Aichi (JP); Tadahiro Ohmi, Miyagi (JP)

Correspondence Address: OBLON, SPIVAK, MCCLELLAND MAIER & NEUSTADT, P.C., 1940 DUKE STREET, ALEXANDRIA, VA, 22314, US

(73) Assignees: TOKYO ELECTRON LIMITED, Minato-ku (JP); NATIONAL UNIVERSITY CORPORATION TOHOKU UNIVERSITY, Sendai-shi (JP)

(21) Appl. No.: 12/279,405

(22) PCT Filed: Feb. 13, 2007
(86) PCT No.: PCT/JP2007/052520

§ 371 Date: Oct. 21, 2008

(30) Foreign Application Priority Data
Feb. 14, 2006 (JP) 2006-036916

(51) Int. Cl. H01J 1/62; H01L 21/00; H05B 33/10

(52) U.S. Cl. 313/504; 438/29; 445/66; 257/E21.538

(57) ABSTRACT

Disclosed is a light-emitting device including a first electrode; a second electrode opposite to the first electrode; and an organic layer that is formed between the first electrode and the second electrode and includes a light-emitting layer. The second electrode includes a conductive protection layer that is formed on the organic layer so as to protect the organic layer and a conductive main electrode layer that is formed on the protection layer.

### TECHNICAL FIELD

The present invention relates to a light-emitting device having an organic light-emitting layer between two electrodes and a substrate processing apparatus for forming the light-emitting device.

### BACKGROUND ART

In recent years and continuing to the present, flat display devices capable of being made thin have been put into practical use in place of conventional CRTs (Cathode Ray Tubes). For example, because organic electroluminescence devices have characteristics of emitting light by themselves and responding at high speed, they have been drawing attention as next-generation display devices. Furthermore, the organic electroluminescence devices may be used not only as display devices but also as surface emitting devices.

The light-emitting device has an organic layer including an organic EL layer (light-emitting layer) between an anode (positive electrode) and a cathode (negative electrode). In the structure of the light-emitting device, holes and electrons are injected from the positive electrode and the negative electrode, respectively, to the light-emitting layer and then reunite together, thereby causing the light-emitting layer to emit light.

Furthermore, the organic layer may additionally have layers for providing excellent light-emitting efficiency, such as a hole transportation layer or an electron transportation layer, between the anode and the light-emitting layer or between the cathode and the light-emitting layer as occasion demands.

As a method of forming the above light-emitting device, the following method is generally employed. First, the organic layer is formed on a substrate, on which the anode made of ITO is patterned, by an evaporation method. The evaporation method is to place an evaporated or sublimated evaporation material onto a substrate to be processed so as to form a thin film. Next, Al (aluminum) as the cathode is formed on the organic layer by the evaporation method. Such a light-emitting device is sometimes called a top cathode light-emitting device.

The light-emitting device having the organic layer between the anode and the cathode is thus formed.

However, in case that, particularly, a substrate to be processed is large when the cathode is formed by the evaporation method as described above, there is a problem in uniformity in film thickness of the cathode. If the uniformity in film thickness of the cathode becomes insufficient on the surface of a substrate to be processed, the quality of the light-emitting device may be nonuniform on the surface of the substrate to be processed.

In order to solve the problem, it is expected to use a sputtering method more excellent in uniformity in film-forming speed on the surface of a substrate to be processed when the cathode is formed, as compared, for example, with the evaporation method. However, the sputtering method causes more damage to an object on which a film is formed than the evaporation method does.

For example, when the above light-emitting device is formed, the cathode is formed on the organic layer having relatively low mechanical strength. Therefore, when particles of a solid metal such as Al collide with the organic layer at high speed due to the sputtering method, etc., there is a likelihood of causing damage to the organic layer, which may reduce the quality of the light-emitting device. Therefore, it is difficult to employ the sputtering method excellent in uniformity in film thickness so as to form the cathode.

### Patent Document 1: JP-A-2004-225058

### DISCLOSURE OF THE INVENTION

### Problems to be Solved by the Invention

To this end, the present invention has a general object of providing a novel and useful light-emitting device, a method of manufacturing the light-emitting device, and a substrate processing apparatus for manufacturing the light-emitting device.

Furthermore, the present invention has a specific object of providing a light-emitting device of high quality that exhibits a small variation in thickness of an electrode and has less damage to an organic layer, a method of manufacturing the light-emitting device, and a substrate processing apparatus for manufacturing the light-emitting device.

### MEANS FOR SOLVING PROBLEMS

According to a first aspect of the present invention, there is provided a light-emitting device comprising a first electrode; a second electrode opposite to the first electrode; and an organic layer that is formed between the first electrode and the second electrode and includes a light-emitting layer; wherein the second electrode includes a conductive protection layer that is formed on the organic layer so as to protect the organic layer and a conductive main electrode layer that is formed on the protection layer.

According to a second aspect of the present invention, there is provided a method of manufacturing a light-emitting device in which an organic layer including a light-emitting layer is formed between a first electrode and a second electrode, comprising an organic layer forming step for forming the organic layer on the first electrode; and an electrode forming step for forming the second electrode including plural layers on the organic layer; wherein the electrode forming step includes a step for forming a conductive protection layer on the organic layer in such a manner as to form a film on the organic layer without causing damage to the organic layer; and a step for forming a main electrode layer in such a manner as to uniformly form a film on the protection layer.

According to a third aspect of the present invention, there is provided a substrate processing apparatus for manufacturing a light-emitting device that is formed on a substrate to be processed and configured to have an organic layer including a light-emitting layer between a first electrode and a second electrode, the substrate processing apparatus comprising a first film forming unit that forms a conductive protection layer constituting the second electrode on the organic layer while protecting the organic layer; a second film forming unit that forms a main electrode layer constituting the second electrode on the protection layer; and transferring means for transferring the substrate to be processed from the first film forming unit to the second film forming unit.

### EFFECTS OF THE INVENTION

According to the embodiments of the present invention, it is possible to provide a light-emitting device of high quality that exhibits a small variation in thickness of an electrode and has less damage to an organic layer, a method of manufacturing the light-emitting device, and a substrate processing apparatus for manufacturing the light-emitting device.

### BRIEF DESCRIPTION OF THE DRAWINGS

FIG. 1 is a view schematically showing a light-emitting device according to a first embodiment;

FIG. 2A is a view (part 1) showing a method of manufacturing the light-emitting device of FIG. 1;

FIG. 2B is a view (part 2) showing the method of manufacturing the light-emitting device of FIG. 1;

FIG. 2C is a view (part 3) showing the method of manufacturing the light-emitting device of FIG. 1;

FIG. 2D is a view (part 4) showing the method of manufacturing the light-emitting device of FIG. 1;

FIG. 3 is a configuration example of a substrate processing apparatus for manufacturing the light-emitting device of FIG. 1;

FIG. 4 is a configuration example (part 1) of a film forming unit used in the substrate processing apparatus of FIG. 1; and

FIG. 5 is a configuration example (part 1) of the film forming unit used in the substrate processing apparatus of FIG. 1.

### DESCRIPTION OF THE REFERENCE NUMERALS

100: light-emitting device
101: substrate
102: anode
103: organic layer
103A: light-emitting layer
103B: hole transportation layer
103C: hole injection layer
103D: electron transportation layer
103E: electron injection layer
104: cathode
104A: protection layer
104B: main electrode layer
200: film forming unit
200A: internal space
201: processing container
202: evaporation source
202A: raw material
203: heater
204: exhaust line
205: substrate holding base
206: moving rail
207: gate valve
300: film forming unit
300A: internal space
301: processing container
302: substrate holding base
303: target
304: high frequency power source
306: exhaust line
307: gas supplying means
308: gate valve
400A and 400B: load lock chamber
500: preprocessing chamber
600: alignment chamber
700: film forming unit
900A, 900B, and 900C: transferring chamber
900a, 900b, and 900c: transferring means

### BEST MODE FOR CARRYING OUT THE INVENTION

Next, a description is made of embodiments of the present invention referring to the drawings.

### FIRST EMBODIMENT

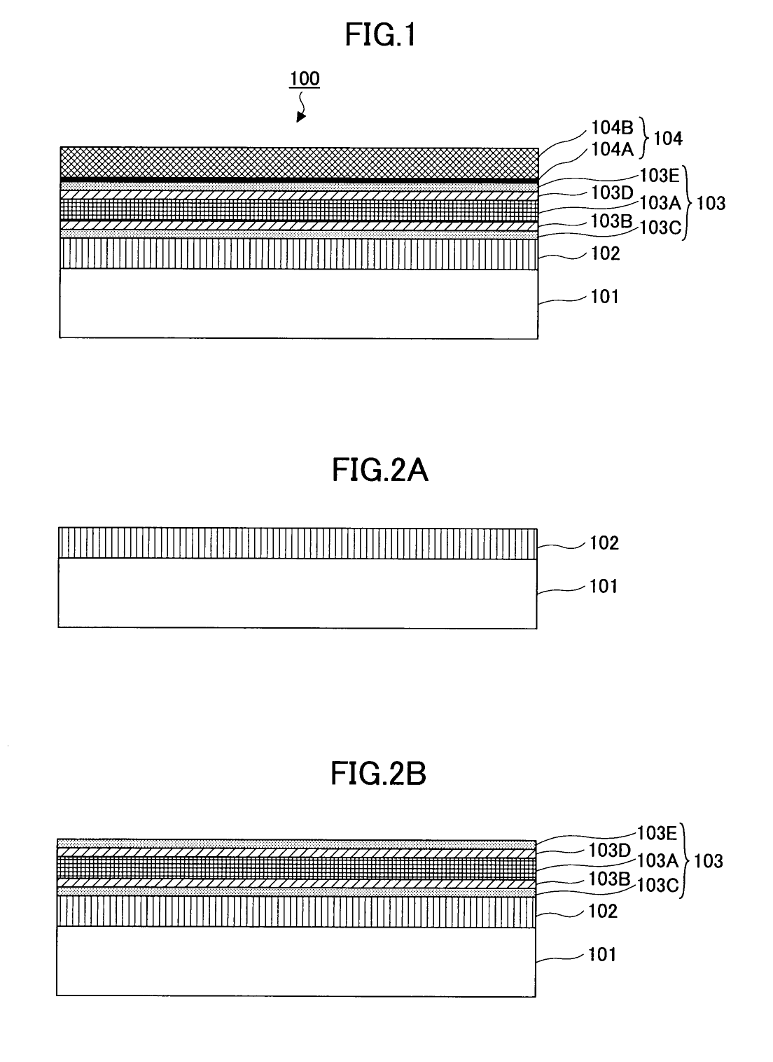

FIG. 1 is a cross-sectional view schematically showing a light-emitting device according to a first embodiment of the present invention. As shown in FIG. 1, a light-emitting device 100 of this embodiment has an anode 102 formed on a substrate 101, a cathode 104 opposite to the anode 102, and an organic layer 103 including a light-emitting layer (organic EL layer) 103A formed between the anode 102 and the cathode 104.

The light-emitting device 100 is sometimes called an organic EL device. In the structure of the light-emitting device 100, when a voltage is applied to a part between the anode 102 and the cathode 104, holes and electrons are injected from the anode 102 and the cathode 104, respectively, to the light-emitting layer 103A and reunited together, thereby causing the light-emitting layer 103A to emit light.

The light-emitting layer 103A is capable of being formed, for example, of materials such as polycyclic aromatic hydrocarbons, hetero-aromatic compounds, and organometallic complex compounds, and these materials are capable of being processed by an evaporation method.

As for a conventional light-emitting device, there are technical problems in forming a cathode as described below. For example, when the cathode is formed by the evaporation method, uniformity in thickness of the cathode may be insufficient. On the other hand, when the cathode is formed by a sputtering method, damage may be caused to an organic layer although the uniformity in thickness of the cathode is excellent.

Accordingly, the light-emitting device 100 of this embodiment is configured so that the cathode 104 includes a conductive protection layer 104A for protecting the organic layer 103 formed on the organic layer 103 so as to contact the same and a conductive main electrode layer 104B formed on the protection layer 104 so as to contact the same.

In this case, for example, the protection layer 104A is preferably formed by the evaporation method, while the main electrode layer 104B is preferably formed by the sputtering method. For example, in the case of forming the cathode 104, the protection layer 104A is first formed by the evaporation method that has less damage to the organic layer 103, and then the main electrode layer 104B is formed on the protection layer 104A by the sputtering method excellent in uniformity in a film formed on the surface of a substrate. In this case, both of the protection layer 104A and the main electrode layer 104B are preferably made of conductive materials. According to a conventional evaporation method, a variation in film thickness is on the order of plus or minus 10%. However, according to the method of this embodiment, the variation in film thickness can be reduced to plus or minus 5% or smaller.

Therefore, as its characteristics, the light-emitting device 100 has less damage to the organic layer 103 and is excellent in uniformity in film thickness of the cathode 104 on the surface of the substrate.

Furthermore, the protection layer 104A and the main electrode layer 104B may be made of the same material, but they may be made of materials different from each other as occasion demands. In either case, the protection layer 104A is made thinner than the main electrode layer 104B.

For example, in the case of a so-called top cathode light-emitting device as in the light-emitting device 100, the cathode 104 is used as a reflection layer for the light emitted from the light-emitting layer 103A. Therefore, the reflectivity of visible light on the protection layer 104A is preferably higher than that of visible light on the main electrode layer 104B. In this case, the light-emitting efficiency of the light-emitting device becomes excellent.

Furthermore, on the other hand, the durability of the main electrode layer 104B is preferably higher than that of the protection layer 104A. Because the main electrode layer 104B is formed at the outer side of the protection layer 104A and exposed to heat and oxygen, it has preferably high durability to oxygen.

Note that in this case the durability is a collective term representing resistance to corrosion caused by active gas such as oxygen and hydrogen or excited active gas, resistance to coarsening, resistance to aggregation, etc. (hereinafter the same applies).

As for the cathode of the conventional light-emitting device, it is difficult to increase the reflectivity of visible light and enhance the durability. On the other hand, the cathode 104 of this embodiment is configured to include plural layers composed of the protection layer 104A formed on the organic layer 103 and the conductive main electrode layer 104B formed on the protection layer 104, thus making it possible to increase the reflectivity of visible light and enhance the durability of the cathode.

The protection layer 104A is preferably made of Ag. Because Ag has a high reflectivity of visible light, it is preferably used as a material of the protection layer 104A facing the light-emitting layer 103A.

Furthermore, the main electrode layer 104B may be made of a material obtained by adding an additive for enhancing durability to Ag. For example, when a material obtained by adding 1% by weight of Pd to Ag is used for the main electrode layer 104B, the durability of the main electrode layer is preferably enhanced compared with a case where Ag is used as a material for the main electrode layer 104B.

Furthermore, the main electrode layer 104B may be made of Al. Al is inferior to Ag in the reflectivity of visible light, but its durability is higher than that of Ag. Therefore, the durability of the main electrode layer is preferably enhanced compared with the case where Ag is used as the material for the main electrode layer 104B.

Furthermore, as described above, the protection layer 104A and the main electrode layer 104B may be made of the same material. For example, the combination of the materials of the protection layer 104A and the main electrode layer 104B may be of Ag and Ag, Al and Al, or Ag (obtained by adding 1% by weight of Pd to Ag) and Ag (obtained by adding 1% by weight of Pd to Ag).

Furthermore, the protection layer 104B is formed so as to contact the organic layer 103. Therefore, materials for adjusting a work function of the protection layer 104 (for providing excellent light-emitting efficiency), such as Li, LiF, and CsCO₃, may be added to the protection layer 104B. Furthermore, a layer (Li, LiF, CsCO₃) for adjusting the work function may be formed on the organic layer 103 as a foundation layer, on which the protection layer 104B made of a highly conductive material such as Ag and Al is formed.

Furthermore, in order to provide the light-emitting layer 103A with excellent light-emitting efficiency, the organic layer 103 may, for example, have a hole transportation layer 103B and a hole injection layer 103C between the light-emitting layer 103A and the anode 102. Furthermore, either one of or both of the hole transportation layer 103B and the hole injection layer 103C may be eliminated.

Similarly, in order to provide the light-emitting layer 103A with excellent light-emitting efficiency, the organic layer 103 may have, for example, an electron transportation layer 103D and an electron injection layer 103E between the light-emitting layer 103A and the cathode 104. Furthermore, either one of or both of the electron transportation layer 103D and the electron injection layer 103E may be eliminated.

Furthermore, the light emitting layer 103A can be formed using, for example, an aluminoquinolinol complex (Alq3) as a host material and rubrene as a doping material. However, without being limited to these materials, it is possible to use various ones to form the light emitting layer 103A.

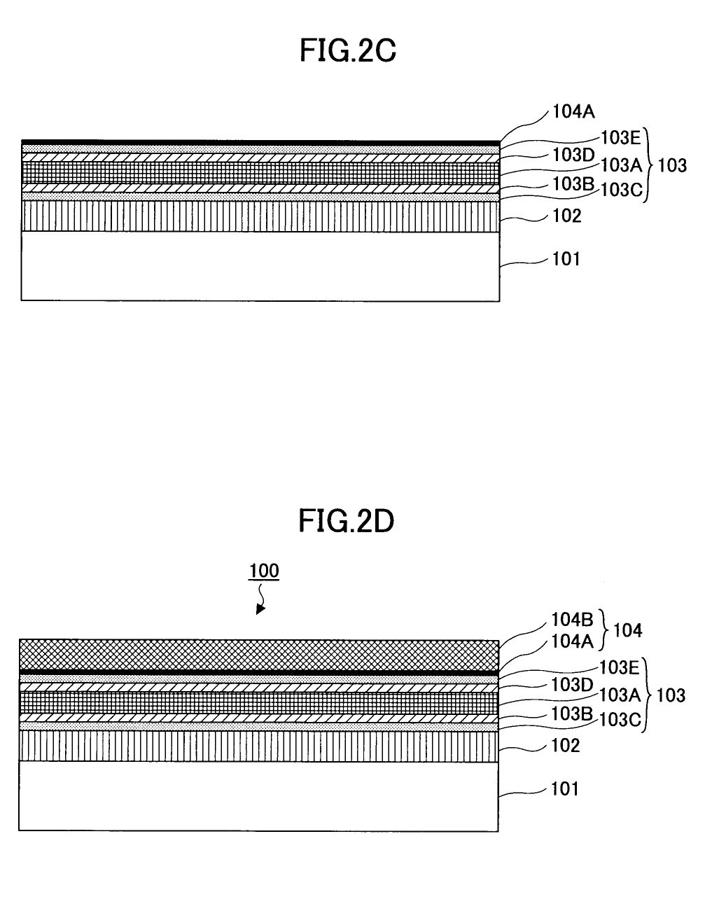

Next, referring to FIGS. 2A through 2D, a description is made of a method of manufacturing the light-emitting device 100 step by step. Note that the same constituents as those described above are denoted by the same reference numerals and the description thereof may be omitted.

First, in a step shown in FIG. 2A, the substrate 101 made of glass on which the anode 102 made of ITO is formed is prepared. In this case, the substrate 101 may have formed thereon an active matrix driving circuit, etc., that is connected to the anode 101 and includes TFTs (Thin Film Transistors).

Next, in a step shown in FIG. 2B, the organic layer 103 is formed on the anode 102 (the substrate 101). In this case, the organic layer 103 is formed, for example, by the evaporation method in which the hole injection layer 103C, the hole transportation layer 103B, the light-emitting layer (organic EL layer) 103A, the electron transportation layer 103D, and the electron injection layer 103E are laminated in this order from the side of the anode 102. Furthermore, as described above, either one of or both of the hole transportation layer 103B and the hole injection layer 103C may be eliminated as occasion demands. Similarly, either one of or both of the electron transportation layer 103D and the electron injection layer 103E may be eliminated as occasion demands.

Then, in steps shown in FIGS. 2C and 2D, the cathode 104 including the plural layers (the protection layer 104A and the main electrode layer 104B) is formed on the organic layer 103.

First, in the step shown in FIG. 2C, the conductive protection layer 104A made, for example, of Ag is formed on the organic layer 103 (the electron injection layer 103E) so as to contact the same by the evaporation method. In this case, the protection layer 104A is formed by the evaporation method. Therefore, damage to the organic layer 103 (the electron injection layer 103E) can be reduced compared with a case where a film is formed by the sputtering method.

Furthermore, in this case, the material constituting the protection film 104A is not limited to Ag. For example, the protection layer 104A may be made of Al or the material obtained by adding an additive (for example, 1% by weight of Pd) for enhancing the durability to Ag. However, Al and the material obtained by adding the additive for enhancing the durability to Ag are inferior to the material having Ag as a major component in the reflectivity of visible light. Therefore, in order to maintain a high reflectivity for reflecting the light emitted from the light-emitting layer 103A, the protection layer 104A is preferably made of Ag.

In this case, “the protection film 104A is made of Ag” represents that the protection film 104A is made of substantially pure Ag or that the protection film 104A is made of a material having at least Ag as a major component. Furthermore, “the material having at least Ag as a major component” represents a material maintaining the purity of Ag at a high level to a degree so as not to substantially reduce the reflectivity of emitted light compared with substantially pure Ag.

Next, in the step shown in FIG. 2D, the main electrode layer 104B made, for example, of Al is formed on the protection layer 104A so as to contact the same by the sputtering method. As a result, the cathode 104 including the protection layer 104A and the main electrode layer 104B is formed.

In this case, because the organic layer 103 (the electron injection layer 103E) is covered and protected by the protection layer 104A, there is less damage to the organic layer 103 caused when the main electrode layer 104B is formed. Therefore, according to this embodiment, the degree of freedom in forming the main electrode layer 104B is increased. For example, the sputtering method, which is excellent in uniformity in film-forming speed on the surface of a substrate while having much damage to an object on which a film is formed, can be selected as the film forming method for forming the main electrode layer 104B. In this case, because the organic layer 103 is protected even if the main electrode layer 104B is formed by the sputtering method, damage to the organic layer 103 is reduced.

In other words, according to the method of manufacturing the light-emitting device of this embodiment, it is possible to manufacture a light-emitting device of high quality that exhibits a small variation in thickness of the cathode and has less damage to the organic layer.

Furthermore, the durability of the main electrode layer 104B is preferably higher than that of the protection layer 104A.

For example, when Al or a material having Al as a major component is used as a material for the main electrode layer 104B, it is superior to Ag in durability although inferior to Ag in the reflectivity of visible light, which preferably enhances the durability of the main electrode layer. Furthermore, the protection layer 104B may be made of the material obtained by adding an additive (for example, Pd) for enhancing the durability to Ag. The light-emitting device 100 of this embodiment can be thus manufactured.

The thickness of the anode 102 is formed in the range 100 μm through 200 μm, the thickness of the organic layer 103 is formed in the range 50 μm through 200 μm, the thickness of the cathode 104 is formed in the range 50 μm through 300 μm, and the thickness of the protection layer 104A is formed in the range 10 μm through 30 μm. Furthermore, the thickness of the protection layer 104A is preferably formed to be one-tenth of that of the main electrode layer 104B.

Furthermore, the light-emitting device 100 can be applied not only to display devices (organic EL display devices) and surface light-emitting devices (illuminations, light sources, etc.), but also to various electronic equipment items.

### SECOND EMBODIMENT

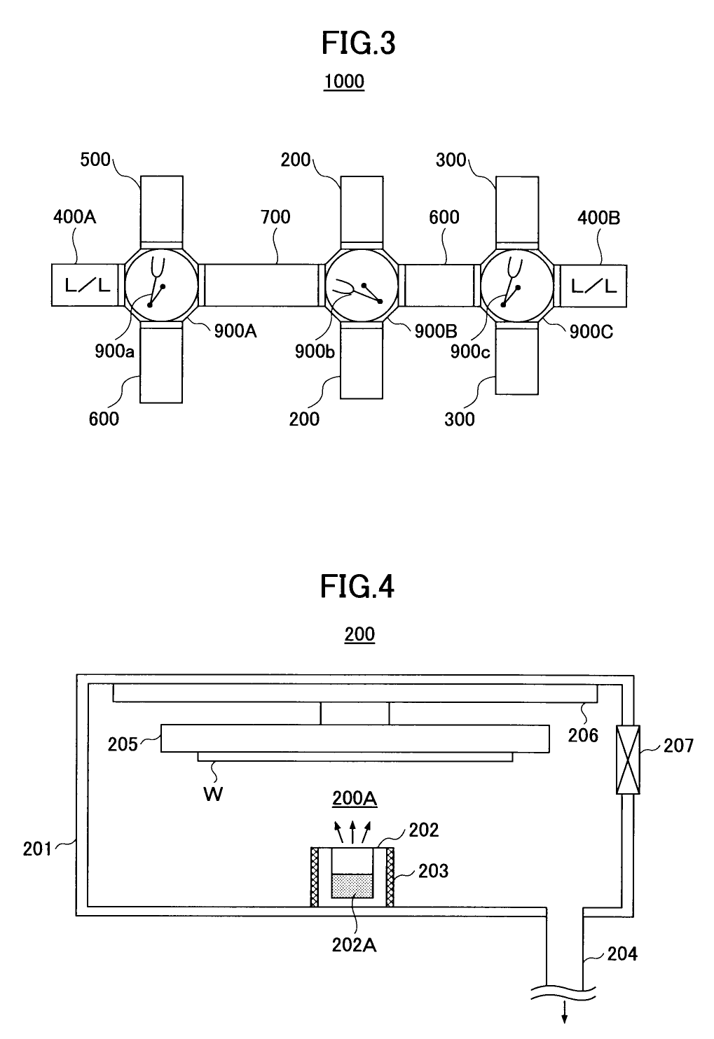

Next, referring to FIGS. 3 through 5, a description is made of an example of the configuration of a substrate processing apparatus for manufacturing the light-emitting device 100 described in the first embodiment.

First, FIG. 3 is a plan view schematically showing an example of the configuration of a substrate processing apparatus 1000 for manufacturing the light-emitting device 100.

As shown in FIG. 3, the substrate processing apparatus 1000 of this embodiment has a configuration in which plural film forming units and processing chambers are connected to one of transferring chambers 900A, 900B, and 900C to which a substrate to be processed is transferred. The transferring chambers 900A, 900B, and 900C have four connection surfaces, each of which is connected to a processing chamber or a film forming unit. Furthermore, the transferring chambers 900A, 900B, and 900C have transferring means (transferring arms) 900a, 900b, and 900c, respectively, for transferring a substrate to be processed.

The processing chambers and the film forming units connected to the transferring chambers 900A, 900B, and 900C are a preprocessing chamber 500 that performs preprocessing (cleaning) of a substrate to be processed, alignment processing chambers 600 that perform alignment (positioning) of a substrate to be processed or a mask to be attached to the substrate to be processed, a film forming unit 700 that forms the organic layer 103 by the evaporation method (that performs the step shown in FIG. 2), film forming units 200 that form the protection layer 104A by the evaporation method (that perform the step shown in FIG. 2C), film forming units 300 that form the main electrode layer 104B by the sputtering method (that perform the step shown in FIG. 2D), and load lock chambers 400A and 400B.

The load lock chamber 400A, the preprocessing chamber 500, the alignment processing chamber 600, and the film forming unit 700 are connected to the four connection surfaces of the transferring chamber 900A. Furthermore, one connection surface of the transferring chamber 900B is connected to the side of the film forming unit 700 opposite to the side thereof connected to the transferring chamber 900A is connected to, and other connection surfaces of the transferring chamber 900B are connected to the corresponding two film forming units 200 and the alignment processing chamber 600. Moreover, one connection surface of the transferring chamber 900C is connected to the side of the alignment processing chamber 600 opposite to the side thereof connected to the transferring chamber 900B, and other connection surfaces of the transferring chamber 900C are connected to the corresponding two film forming units 300 and the load lock chamber 400B.

Furthermore, the transferring chambers 900A, 900B, and 900C, the load lock chambers 400A and 400B, the preprocessing chamber 500, the alignment processing chamber 600, and the film forming units 200, 300, and 700 are each connected to exhaust means (not shown) such as a vacuum pump for reducing the pressure inside them (for producing a vacuum state), and they are maintained in a pressure-reduced state as occasion demands.

Next, a description is made of the outline of a procedure for manufacturing the light-emitting device 100 described in the first embodiment. First, a substrate W to be processed (equivalent to the substrate 101 shown in FIG. 2A on which the anode 102 is formed) is put into the substrate processing apparatus 1000 from the load lock chamber 400A. The substrate W put into the load lock chamber 400A is transferred to the preprocessing chamber 500 via the transferring chamber 900A by the transferring means 900a and subjected to the preprocessing (cleaning).

Then, the substrate W is transferred to the alignment processing chamber 600 via the transferring chamber 900A by the transferring means 900a and coated with a mask. Next, the substrate W is transferred to the film forming unit 700 via the transferring chamber 900A by the transferring means 900a. In the film forming unit 700, the organic layer 103 of the light-emitting device 100 is formed by the evaporation method (the step shown in FIG. 2B is performed).

Next, the substrate W on which the organic layer 103 is formed is transferred to the alignment processing chamber 600 via the transferring chamber 900B by the transferring means 900b and subjected to the alignment. Then, the substrate W is transferred to the film forming unit 200 (one of the film forming units connected to the transferring chamber 900B) by the transferring means 900b.

In the film forming unit 200, the protection layer 104A is formed on the substrate W transferred to the film forming unit 200 by the evaporation method (the step shown in FIG. 2C is performed). The substrate W on which the protection layer 104A is formed is transferred to the alignment processing chamber 600 and subjected to the alignment. After that, the substrate W is transferred to the film forming unit 300 (one of the two film forming units 300 connected to the transferring chamber 900C) via the transferring chamber 900C by the transferring means 900c.

In the film forming unit 300, the main electrode layer 104B is formed by the sputtering method (the step shown in FIG. 2D is performed). The light-emitting device 100 described in the first embodiment is thus formed, and it is then taken out from the substrate processing apparatus 1000 via the load lock chamber 400B. Note that the substrate processing apparatus 1000 may further include a film forming unit that forms a protection layer consisting, for example, of an insulation layer on the light-emitting device 100.

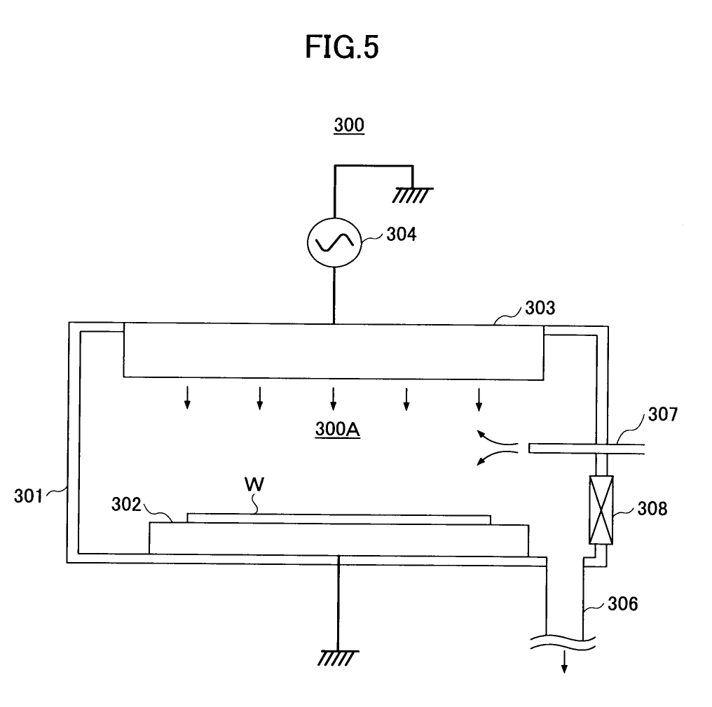

Next, a description is made of an example of the configurations of the film forming unit 200 and the film forming unit 300 referring to FIGS. 4 and 5, respectively.

FIG. 4 is an illustration schematically showing an example of the configuration of the film forming unit (evaporation unit) 200 included in the substrate processing apparatus 1000.

As shown in FIG. 4, the film forming unit 200 has a processing container 201 in which an internal space 200A is partitioned. In the internal space 200A, an evaporation source 202 and a substrate holding base 205 are provided. The internal space 200A is exhausted through an exhaust line 204 connected to exhaust means (not shown) such as an exhaust pump and is maintained in a predetermined pressure-reduced state.

The evaporation source 202 is provided with a heater 203. The heater 203 is capable of heating a raw material 202 held inside it and evaporating or sublimating the same so as to become a gas raw material. The gas raw material 202A is collected on the substrate W (the substrate 101 on which the anode 102 and the organic layer 103 are formed) held on the substrate holding base 205 arranged to be opposite to the evaporation source 202, thereby forming the protection layer 104A.

The substrate holding base 205 is capable of moving parallel on a moving rail 206 arranged on the upper surface (on the side opposite to the evaporation source 202) of the processing container 201. With the movement of the holding base 205 at the time of forming a film, uniformity in an evaporation film on the surface of a substrate to be processed becomes excellent.

Furthermore, with the opening of a gate valve 207 formed on the side connected to the transferring chamber 900B of the processing container 201, it becomes possible to put the substrate W into the internal space 200A and take it out from the internal space 200A.

Through the step equivalent to FIG. 2C described in the first embodiment using the film forming unit 200, it becomes possible to form the protection layer 104A while reducing damage to the organic layer 103.

Furthermore, FIG. 5 is an illustration schematically showing an example of the configuration of the film forming unit (sputtering unit) 300 included in the substrate processing apparatus 1000.

As shown in FIG. 5, the film forming unit 300 has a processing container 301 in which an internal space 300A is partitioned. In the internal space 300A, a target (cathode) 303 and a substrate holding base (anode) 302 are provided. The internal space 300A is exhausted through an exhaust line 306 connected to exhaust means (not shown) such as an exhaust pump and is maintained in a predetermined pressure-reduced state.

The internal space 300A is supplied with gas for plasma excitation such as Ar from gas supplying means 307. When high frequency power is applied to the target 303 from a high frequency power source 304, plasma is excited in the internal space 300A to generate Ar ions. The target 303 sputters the substrate W by the Ar ions thus generated. Accordingly, the main electrode layer 104B is formed on the substrate W (the anode 102, the organic layer 103, the substrate 101 on which the protection layer 104A is formed) held on the substrate holding base 302.

Furthermore, with the opening of a gate valve 308 formed on the side connected to the transferring chamber 900C, it becomes possible to put the substrate W into the internal space 300A and take it out from the internal space 300A.

Furthermore, the configurations of the film forming unit (evaporation unit) 200 and the film forming unit (sputtering unit) 300 are just examples, and they can be formed and modified in various ways.

Furthermore, it is clear that the shape of the transferring chamber, the number of the connection surfaces, the configuration and the number of the processing chambers and the film forming units to be connected, etc., can be formed and modified in various ways.

The present invention is not limited to the specifically disclosed embodiment, and variations and modifications may be made without departing from the scope of the present invention.

### INDUSTRIAL APPLICABILITY

According to the embodiments of the present invention, it is possible to provide a light-emitting device of high quality that exhibits a small variation in thickness of an electrode and has less damage to an organic layer, a method of manufacturing the light-emitting device, and a substrate processing apparatus for manufacturing the light-emitting device.

The present application is based on Japanese Priority Application No. 2006-36916 filed on February 14, 2006, the entire contents of which are hereby incorporated herein by reference.

1. A light-emitting device comprising:
a first electrode;
a second electrode opposite to the first electrode; and
an organic layer that is formed between the first electrode and the second electrode and includes a light-emitting layer; wherein
the second electrode includes a conductive protection layer that is formed on the organic layer so as to protect the organic layer and a conductive main electrode layer that is formed on the protection layer.

2. The light-emitting device according to claim 1, wherein
the protection layer is formed by an evaporation method.

3. The light-emitting device according to claim 2, wherein
the main electrode layer is formed by a sputtering method.

4. The light-emitting device according to claim 1, wherein
a reflectivity of visible light on the protection layer is higher than a reflectivity of visible light on the main electrode layer.

5. The light-emitting device according to claim 1, wherein
durability of the main electrode layer is higher than durability of the protection layer.

6. The light-emitting device according to claim 1, wherein
the protection layer is made of Ag, and the main electrode layer is made of a material obtained by adding an additive for enhancing durability to Ag.

7. The light-emitting device according to claim 1, wherein
the protection layer is made of Ag, and the main electrode layer is made of a material having Al as a major component.

8. A method of manufacturing a light-emitting device in which an organic layer including a light-emitting layer is formed between a first electrode and a second electrode, comprising:
an organic layer forming step for forming the organic layer on the first electrode; and
an electrode forming step for forming the second electrode including plural layers on the organic layer; wherein
the electrode forming step includes a step for forming a conductive protection layer on the organic layer in such a manner as to form a film on the organic layer without causing damage to the organic layer; and
a step for forming a main electrode layer in such a manner as to form a uniform film on the protection layer.

9. The method of manufacturing a light-emitting device according to claim 8, wherein
the protection layer is formed by an evaporation method.

10. The method of manufacturing a light-emitting device according to claim 9, wherein
the main electrode layer is formed by a sputtering method.

11. The method of manufacturing a light-emitting device according to claim 8, wherein
a reflectivity of visible light on the protection layer is higher than a reflectivity of visible light on the main electrode layer.

12. The method of manufacturing a light-emitting device according to claim 8, wherein
durability of the main electrode layer is higher than durability of the protection layer.

13. The method of manufacturing a light-emitting device according to claim 8, wherein
the protection layer is made of Ag, and the main electrode layer is made of a material obtained by adding an additive for enhancing durability to Ag.

14. The method of manufacturing a light-emitting device according to claim 8, wherein
the protection layer is made of Ag, and the main electrode layer is made of a material having Al as a major component.

15. A substrate processing apparatus for manufacturing a light-emitting device that is formed on a substrate to be processed and configured to have an organic layer including a light-emitting layer between a first electrode and a second electrode, the substrate processing apparatus comprising:
a first film forming unit that forms a conductive protection layer constituting the second electrode on the organic layer while protecting the organic layer;
a second film forming unit that forms a main electrode layer constituting the second electrode on the protection layer; and
transferring means for transferring the substrate to be processed from the first film forming unit to the second film forming unit.

16. The substrate processing apparatus according to claim 15, wherein
the first film forming unit is an evaporation unit.

17. The substrate processing apparatus according to claim 16, wherein
the second film forming unit is a sputtering unit.
